(19) United States
(12) Patent Application Publication
(10) Pub. No.: US 2024/0208001 A1
(43) Pub. Date: Jun. 27, 2024

(54) SUBSTRATE TREATING APPARATUS INCLUDING ECCENTRICITY CORRECTION UNIT, AND SUBSTRATE TREATING METHOD

(71) Applicant: SEMES CO., LTD., Chungcheongnam-do (KR)

(72) Inventors: In Ki JUNG, Gyeonggi-do (KR); Jeong Hyup YU, Gyeonggi-do (KR)

(21) Appl. No.: 18/384,384

(22) Filed: Oct. 27, 2023

(30) Foreign Application Priority Data
Dec. 21, 2022 (KR) 10-2022-0180062

(51) Int. Cl. B24B 49/04; B24B 5/04

(52) U.S. Cl. CPC B24B 49/04; B24B 5/04

(57) ABSTRACT

A substrate treatment apparatus including an eccentricity correction unit correcting eccentricity of a substrate supported by a support unit, the substrate treatment apparatus includes a first correction unit including a first contact portion in contact with a plurality of points of a side surface of the substrate having a notch formed in a periphery thereof, and a first drive unit configured to move a position of the substrate such that a center of the substrate corresponds to a center of the support unit, and a second correction unit including a second contact portion in contact with the other side surface of the substrate having the notch formed in the periphery thereof, a second drive unit configured to change a position of the second contact portion, and an elastic portion configured to provide elastic force in a direction of movement of the second contact portion to press or depressurize the substrate.

### CROSS-REFERENCE TO RELATED APPLICATION(S)

This application claims benefit of priority to Korean Patent Application No. 10-2022-0180062 filed on Dec. 21, 2022 in the Korean Intellectual Property Office, the disclosure of which is incorporated herein by reference in its entirety.

### BACKGROUND

### 1. Field

The present disclosure relates to a substrate treatment apparatus including an eccentricity correction unit, and a substrate treating method. Specifically, the present disclosure relates to a substrate treatment apparatus and substrate method treating in which eccentricity correction is performed without identifying a notch, using an eccentricity correction unit having a small notch error.

### 2. Description of Related Art

In general, in order to manufacture semiconductor devices, various processes such as a photo process, an etching process, an ion implantation process, and a deposition process are performed. In each process, liquid is supplied to a substrate to perform predetermined treatment.

In various processes for treating a substrate, the substrate needs to be mounted in a correct position on a support unit. For example, in a liquid treatment process in which liquid is supplied to a substrate, when the substrate is disposed in a position offset from the correct position on the support unit, a spotting point of the liquid supplied to the substrate is shifted. In this case, the liquid is not uniformly applied to the substrate or is not targeted and supplied accurately to a specific point on the substrate, thereby preventing uniform liquid treatment of the substrate. In addition, in a process of treating a substrate using plasma, when the substrate is mounted in a position offset from the correct position on the support unit, a sheath of the plasma formed on an upper side of the substrate may be changed to prevent uniform plasma treatment of the substrate. In particular, in a process of etching a thin film or impurities formed on an edge region of the substrate, when the substrate is not mounted in the correct position on the support unit, it may be difficult to uniformly etch the edge region of the substrate, resulting in a decrease in yield of the treated substrate.

Therefore, in order to mount the substrate in the correct position, eccentricity correction of the substrate needs to be performed. However, a notch may be formed in a periphery of the substrate to detect direction, and thus a notch error may occur when measuring eccentricity by contact with the notch of the substrate. In particular, when a contact portion, in contact with the substrate for eccentricity correction, has a convex round shape having a large curvature, a notch error, a distance between a point at which the contact portion expects the substrate to be present and a central point of the round, increases, and thus exceeds a preset allowable eccentricity value. Eccentricity correction is performed on the notch, and inaccurate eccentricity correction, reflecting the notch error, is performed.

In addition, in order to prevent a mixture of substrate eccentricity and a notch error from interfering with eccentricity correction, eccentricity measurement and correction needs to be performed on a periphery of the substrate excluding the notch. It is necessary to detect the notch of the substrate, to perform control for avoiding the notch from separately control for eccentricity correction, and to determine whether the periphery of the substrate, excluding the notch, is eccentric. Accordingly, it is inconvenient to perform control, and an error is highly likely to be occur in the process of correcting substrate eccentricity.

### SUMMARY

An aspect of the present disclosure provides a substrate treatment apparatus and a substrate treating method including an eccentricity correction unit configured to treat a substrate uniformly, and to ensure that a notch error does not affect eccentricity correction even when substrate eccentricity measurement is performed on any side surface of a substrate having a notch formed in a periphery thereof.

According to another aspect of the present disclosure, there is provided a substrate treatment apparatus including an eccentricity correction unit correcting eccentricity of a substrate supported by a support unit, the substrate treatment apparatus includes a first correction unit including a first contact portion in contact with a plurality of points of a side surface of the substrate having a notch formed in a periphery thereof, and a first drive unit configured to move a position of the substrate such that a center of the substrate corresponds to a center of the support unit, and a second correction unit including a second contact portion in contact with the other side surface of the substrate having the notch formed in the periphery thereof, a second drive unit configured to change a position of the second contact portion, and an elastic portion configured to provide elastic force in a direction of movement of the second contact portion to press or depressurize the substrate. A portion of the second contact portion in contact with the other side surface of the substrate may be configured to be flat.

According to another aspect of the present disclosure, there is provided a substrate treatment apparatus including an eccentricity correction unit correcting eccentricity of a substrate supported by a support unit, the substrate treatment apparatus including a first correction unit including a first contact portion in contact with a plurality of points of a side surface of the substrate having a notch formed in a periphery thereof, and a first drive unit configured to move a position of the substrate such that a center of the substrate corresponds to a center of the support unit, and a second correction unit including a second contact portion in contact with the other side surface of the substrate having the notch formed in the periphery thereof, a second drive unit configured to change a position of the second contact portion, and an elastic portion configured to provide elastic force in a direction of movement of the second contact portion to press or depressurize the substrate. The first correction unit may be in contact with a plurality of points, sharing one axis on a horizontal plane, among the points. The second correction unit may be in contact with a point belonging to an axis, different from the one axis.

According to another aspect of the present disclosure, there is provided a method for treating a substrate, the method including a preparation operation of mounting a substrate to be treated on a support unit, an eccentricity measurement operation of measuring eccentricity of the substrate having a notch formed in a periphery thereof, an eccentricity correction operation of correcting eccentricity of the substrate depending on a degree of eccentricity of the substrate measured in the eccentricity measurement operation, and a treatment operation of treating the substrate having corrected eccentricity. In the eccentricity correction operation, a center of the substrate to be treated may be allowed to correspond to a center of a chuck within an error range by contact with a plurality of points, sharing one axis, of a side surface of the substrate supported by the chuck and a point belonging to an axis, different from the one axis. The eccentricity correction operation may be performed in the same manner, even when the notch is included at the point.

According to an example embodiment of the present disclosure, an eccentricity correction unit may measure eccentricity and perform eccentricity correction without the need to perform a control for detecting a notch or avoiding the notch in a process of correcting eccentricity, thereby improving reliability of an apparatus and minimizing an error.

In addition, according to an example embodiment of the present disclosure, a shape of the eccentricity correction unit may be limited to minimize a notch error occurring during contact with the notch, thereby simplifying an eccentricity correction process.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a process chamber according to an example embodiment of the present disclosure;

FIG. 2 is a top cross-sectional view of a process chamber in which an eccentricity correction unit is installed according to an example embodiment of the present disclosure;

FIG. 3 illustrates a portion of an eccentricity correction unit including a second correction unit according to an example embodiment of the present disclosure;

FIGS. 4A and 4B illustrate a portion of an eccentricity correction unit including a second correction unit according to another example embodiment of the present disclosure;

FIG. 5 illustrates a substrate W′ before correction is performed and a substrate W on which correction is performed according to an example embodiment of the present disclosure;

FIG. 6 illustrates an eccentricity correction method according to an example embodiment of the present disclosure; and

FIG. 7 illustrates a specific eccentricity correction method according to an example embodiment of the present disclosure.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

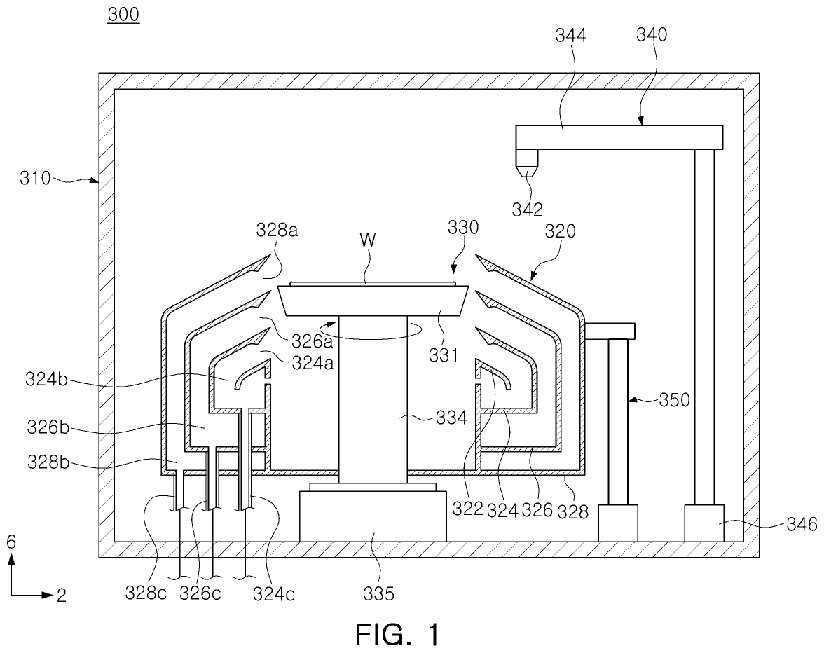

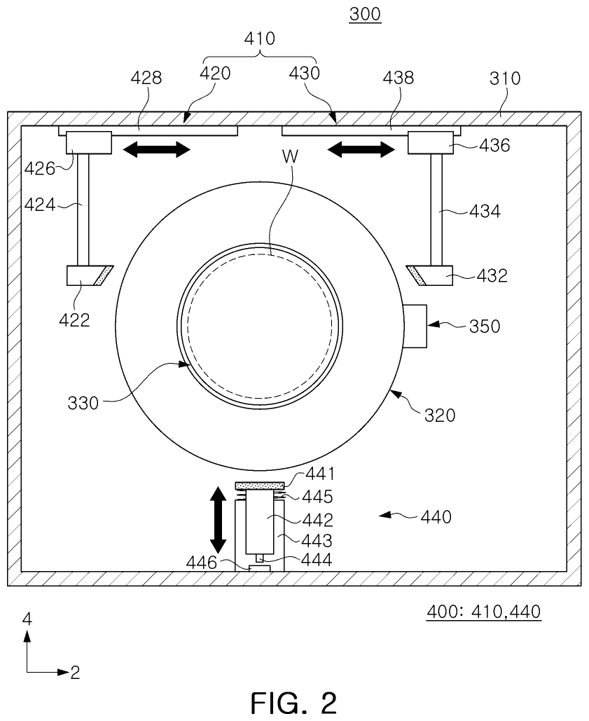

FIG. 1 is a schematic cross-sectional view of a process chamber according to an example embodiment of the present disclosure. FIGS. 2 to 5 are top cross-sectional views of a process chamber in which eccentricity correction unit is installed according to an example embodiment of the present disclosure.

The process chamber 300 may include a housing 310, a treatment container 320, a support unit 330, a liquid supply unit 340, an elevation unit 350, and an eccentricity correction unit 400.

In FIG. 1, the eccentricity correction unit 400 according to an example embodiment is omitted for ease of understanding. In FIG. 2, the liquid supply unit 340 according to an example embodiment is omitted for ease of understanding. Hereinafter, the housing 310, the treatment container 320, the support unit 330, the liquid supply unit 340, and the elevation unit 350 according to an example embodiment will be described with reference to FIG. 1, and the eccentricity correction unit 400 according to an example embodiment will be described with reference to FIG. 2.

The housing 310 may have a substantially rectangular parallelepiped shape. The housing 310 may have an internal space. In the internal space, the treatment container 320, the support unit 330, the liquid supply unit 340, the elevation unit 350, and the eccentricity correction unit 400 (see FIG. 2) to be described below may be positioned. An entrance/exit opening (not illustrated) may be formed in a sidewall of the housing 310. The entrance/exit opening (not illustrated) may function as a passage through which the substrate W enters or exits the housing 310. Although not illustrated, the bottom of the housing 310 may have an exhaust hole for exhausting atmosphere of the internal space.

The treatment container 320 may be a bowl having an open upper portion. The interior of the treatment container 320 may function as a space in the substrate W is treated. The treatment container 320 may be disposed on the outside of the substrate W, supported by the support unit 330 to be described below, to surround the substrate W.

In an example embodiment, the treatment container 320 may have a guide wall 322 and a plurality of collecting containers 324, 326, and 328. Each of the guide wall 322 and the collecting containers 324, 326, and 328 may have a ring shape, surrounding the support unit 330. The collecting containers 324, 326, and 328 may respectively have collecting spaces 324b, 326b, and 328b for separating and collecting different liquids, among liquids used to treat the substrate W. When a process of supplying liquid to the substrate W to etch an edge region of the substrate W is performed, liquid, scattered by rotation of the substrate W, may flow into the collecting spaces 324b, 326b, and 328b through inlets 324a, 326a, and 328a of the collecting containers 324, 326, and 328.

According to an example embodiment, the treatment container 320 may include a first collecting container 324, a second collecting container 326, and a third collecting container 328. The first collecting container 324 may be disposed to surround the support unit 330, the second collecting container 326 may be disposed to surround the first collecting container 324, and the third collecting container 328 may be disposed to surround the second collecting container 326. A first inlet 324a through liquid flows into a collecting space 324b of the first collecting container 324 may be positioned below a second inlet 326a through liquid flows into a collecting space 326b of the second collecting container 326. In addition, the second inlet 326a may be positioned below a third inlet 328a through which liquid flows into a collecting space 328b of the third collecting container 328. Liquid discharge pipes 324c, 326c, and 328c for discharging liquid may be respectively coupled to the collecting containers 324, 326, and 328. The liquid, discharged through the liquid discharge pipes 324c, 326c, and 328c, may be reused using an external regeneration system (not illustrated).

The number of collecting containers described above may vary depending on the number of liquids used and the number of liquids to be collected or discarded. Although not illustrated, an exhaust line for exhausting fume and gas may be connected to the bottom of the treatment container 320.

The support unit 330 may support and rotate the substrate W. The support unit 330 may include a chuck 331 and a spin axis 334. An upper surface of the chuck 331 may have a substantially circular shape. In addition, the upper surface of the chuck 331 may have a diameter greater than that of the substrate W. The substrate W may be mounted on the upper surface of the chuck 331. Accordingly, the chuck 331 may support the substrate W. The chuck 331 may mechanically support the substrate W using a support pin (not illustrated) or the like. However, the present disclosure is not limited thereto, and the chuck 331 may support the substrate W using a vacuum suction method.

The spin axis 334 may have a longitudinal direction, parallel to a third direction 6. One end of the spin axis 334 may be coupled to the chuck 331, and the other end of the spin axis 334 may be coupled to an axis driver 335. More specifically, one end of the spin axis 334 may be coupled to a lower end of the chuck 331, and the other end of the spin axis 334 may be inserted into a hollow formed in a bottom central portion of the treatment container 320 and be coupled to the axis driver 335. The axis driver 335 may rotate the spin axis 334 using the longitudinal direction of the spin axis 334 as a rotation axis. Accordingly, the chuck 331, coupled to the spin axis 334, may also rotate and the substrate W, mounted on the upper surface of the chuck 331, may also rotate. The axis driver 335 may be one of known motors transmitting rotational force. In addition, the axis driver 335 may raise and lower the spin axis 334 in a direction, parallel to the third direction 6.

The liquid supply unit 340 may supply liquid to the substrate W, supported by the support unit 330. The liquid supply unit 340 may include a nozzle 342. The liquid according to an example embodiment may be an etchant for removing a thin film or impurities formed on the substrate W. In addition, the liquid according to an example embodiment may be an etch-blocking liquid for diluting a liquid removing impurities or a thin film formed on the substrate W. According to an example embodiment, the etchant may include an acid such as hydrofluoric acid (HF) or phosphoric acid (P₂O₅). According to an example embodiment, the etch-blocking liquid may be pure. However, the present disclosure is not limited thereto, and the liquid according to an example embodiment may include various types of liquids not exemplified above. That is, the liquid according to an example embodiment may include all various types of liquids used when the substrate W is treated.

The nozzle 342 may be coupled to an arm 344. Accordingly, the nozzle 342 may be supported by the arm 344. The arm 344 may have a substantially “L” shape. The arm 344 may be coupled to an arm driver 346. The arm driver 346 may allow swing movement or straight movement of the arm 344. Accordingly, the nozzle 342 may be moved between a standby position and a liquid supply position by the arm driver 346.

The standby position may be a position in which the nozzle 342 stands by when liquid is not supplied to the substrate W. The liquid supply position may be a position in which the nozzle 342 supplies liquid onto the substrate W. For example, when viewed from above, the nozzle 342 may be positioned to overlap the substrate W in the liquid supply position. More specifically, when an etchant is supplied to the substrate W, the nozzle 342 may be positioned to correspond to an upper side of the edge region of the substrate W. In addition, when the etch-blocking liquid is supplied is onto the substrate W, the nozzle 342 may be positioned to correspond to an upper side of a central region of the substrate W.

The elevation unit 350 may change a position of the treatment container 320. For example, the elevation unit 350 may raise and lower the treatment container 320 in a direction, parallel to the third direction 6. The elevation unit 350 may be one of known motors transmitting driving force. Vertical movement of the treatment container 320 may change a relative height between the treatment container 320 and the substrate W supported by the support unit 330. Accordingly, depending on a type and composition ratio of liquid supplied to the substrate W, the collecting containers 324, 326, and 328 may separate and collect the liquid.

According to an example embodiment, when the substrate W is treated, the elevation unit 350 may move the treatment container 320 in an upward direction such that an upper end of the treatment container 320 is positioned to be higher than an upper end of the substrate W. In addition, when eccentricity of the substrate W is corrected after treatment of the substrate W is completed or before the substrate W is treated, the elevation unit 350 may move the treatment container 320 in a downward direction such that the upper end of the treatment container 320 is positioned to be lower than an upper end of the chuck 331.

The eccentricity correction unit 400 may change a position of the substrate W, mounted on the chuck 331. More specifically, the eccentricity correction unit 400 may correct eccentricity of the substrate W such that a center of the substrate W, mounted on the chuck 331, correspond to a central axis of the chuck 331. The eccentricity correction unit 400 according to an example embodiment may be in contact with a side surface of the substrate W to change the position of the substrate W. A detailed mechanism thereof will be described below.

The eccentricity correction unit 400 may include a first correction unit 410 and a second correction unit 440. The first correction unit 410 and the second correction unit 440 may be installed on sidewalls of the housing 310, respectively. More specifically, the first correction unit 410 may be installed on one sidewall of the housing 310, and the second correction unit 440 may be installed on the other sidewall, opposing the one sidewall of the housing 310 on which the first correction unit 410 is installed. However, the present disclosure is not limited thereto, and installation positions of the first correction unit 410 and the second correction unit 440 may be changed on the sidewalls of the housing 310 in various manners.

The first correction unit 410 may be in contact with a plurality of points on the side surface of the substrate W to change the position of the substrate W and determine the position of the substrate W. According to an example embodiment, when viewed from above, the first correction unit 410 may be in contact with two different points on the same axis to change the position of the substrate W. For example, two different points on the side surface of the substrate W in contact with the first correction unit 410 may all be positioned on an X-axis. That is, the two different points on the side surface of the substrate W in contact with the first correction unit 410 may share an X-axis on a horizontal plane.

The first correction unit 410 may include a first-first correction unit 420 and a first-second correction unit 430.

The first-first correction unit 420 may include a first-first contact portion 422, a first-first arm 424, a first-first drive unit 426, and a first-first rail 428.

The first-first contact portion 422 may be in contact with a first point on the side surface of the substrate W to change the position of the substrate W. One surface of the first-first contact portion 422 may be formed to be inclined. The inclined surface of the first-first contact portion 422 may be a surface in contact with the substrate W. More specifically, the inclined surface of the first-first contact portion 422 may be inclined at an angle corresponding to an angle formed by a tangential direction of the substrate W. In addition, the inclined surface of the first-first contact portion 422 may be formed of a material such as poly-ether-ether-ketone (PEEK) filled with carbon. However, the present disclosure is not limited thereto, and the entire region of the first-first contact portion 422 may be formed of a material the same as PEEK.

The first-first arm 424 may be coupled to the first-first contact portion 422. The first-first arm 424 may have a longitudinal direction, parallel to a second direction 4. The first-first contact portion 422 may be coupled to one end of the first-first arm 424, and the first-first drive unit 426 may be coupled to the other end of the first-first arm 424. The first-first drive unit 426 may be one of known linear motors providing driving force to change a position of the first-first arm 424. In addition, the first-first rail 428 may be installed on one sidewall of the housing 310. The first-first rail 428 may have a longitudinal direction, parallel to a first direction 2. The first-first drive unit 426 may be mounted on the first-first rail 428 to move in a longitudinal direction (for example, the first direction 2) of the first-first rail 428. Accordingly, the first-first arm 424 and the first-first contact portion 422, coupled to the first-first drive unit 426, may also move in the first direction 2, and the first-first contact portion 422 may be in contact with the first point on the side surface of the substrate W to change the position of the substrate W.

The first-second correction unit 430 may include a first-second contact portion 432, a first-second arm 434, a first-second drive unit 436, and a first-second rail 438.

The first-second contact portion 432 may be in contact with a second point on the side surface of the substrate W to change the position of the substrate W. The second point according to an example embodiment may be a point sharing the same X-axis on the horizontal plane as the first point, as described above.

When viewed from above, the first-second contact portion 432, the first-second arm 434, the first-second drive unit 436, and the first-second rail 438 may be respectively symmetrical to the first-first contact portion 422, the first-first arm 424, the first-first drive unit 426, and the first-first rail 428 described above. That is, the first-second contact portion 432, the first-second arm 434, the first-second drive unit 436, and the first-second rail 438 may have a structure the same as or similar to that of the first-first contact portion 422, the first-first arm 424, the first-first drive unit 426, and the first-first rail 428. Accordingly, the following description will focus on the first-first correction unit 420, and a description of the first-second correction unit 430 will be omitted.

Components included in the above-described first-first correction unit 420 and first-second correction unit 430 may be disposed so as not to interfere with the liquid supply unit 340 illustrated in FIG. 2. In addition, the components included in the first-first correction unit 420 and the first-second correction unit 430 may be disposed in a position, not interfering with an entrance/exist opening (not illustrated) formed in the sidewall of the housing 310.

Unlike the above-described example, each of the first-first arm 424 and the first-second arm 434 may have a longitudinal direction, parallel to the first direction 2. In this case, the first-first rail 428 and the first-second rail 438 may not be provided, and the first-first drive unit 426 and the first-second drive unit 436, having a structure such as a cylinder, may respectively move the first-first arm 424 and the first-second arm 434 in a direction, parallel to the first direction 2.

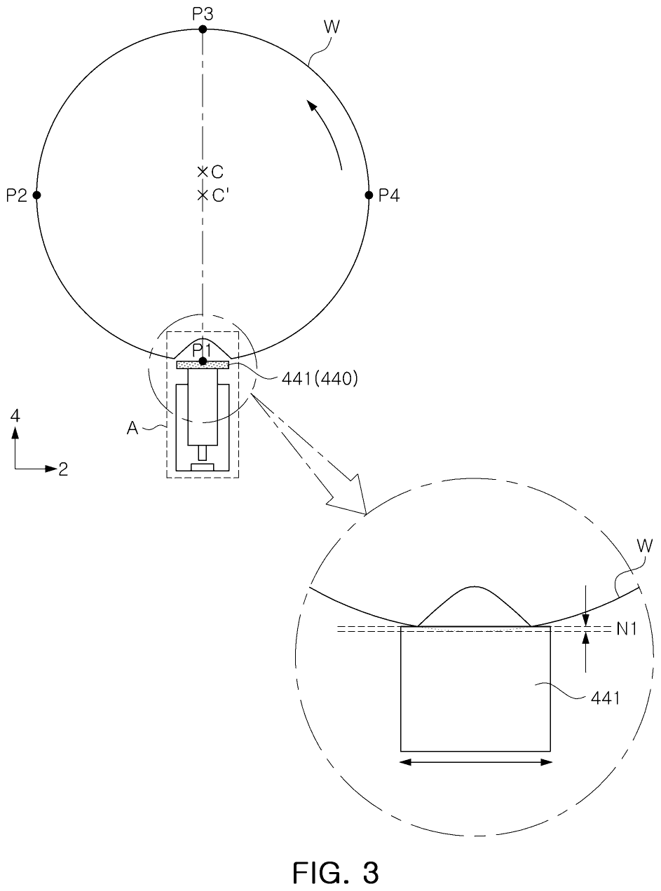

The second correction unit 440 may be in contact with a point on the side surface of the substrate W to change the position of the substrate W. According to an example embodiment, the second correction unit 440 may be in contact with one point on the side surface of the substrate W included on one axis, different from another axis including a plurality of points at which the first correction unit 410 is in contact with the substrate W, on a horizontal plane. That is, the second correction unit 440 may be in contact with a third point on the side surface of the substrate W included on an axis parallel to X-axis, different from an X-axis on the horizontal plane at which the first correction unit 410 is in contact with the substrate W, and may include a second contact portion 441 (see FIG. 3) in contact with the third point on the side surface of the substrate W. For example, when viewed from above, the third point may refer to a lowermost point of the substrate W.

The second correction unit 440 may include a second contact portion 441, a second drive unit 442, a body 443, a guide rail (not illustrated), an elastic portion 445, and a displacement measurement unit 446.

The second contact portion 441 may be in contact with the third point on the side surface of the substrate W. In addition, the second contact portion 441 may be formed of a material the same as PEEK filled with carbon. The second contact portion 441 may be coupled to the second drive unit 442.

The second drive unit 442 may change a position of the second contact portion 441. The second drive unit 442 may be one of known linear motors.

The elastic portion 445 may be disposed between the other surface of the second drive unit 442 and the body 443. More specifically, one end of the elastic portion 445 may be coupled to the other surface of the second drive unit 442, and the other end of the elastic portion 445 may be coupled to the body 443, opposing the other surface of the second drive unit 442. The other surface of the second drive unit 442 may be a surface, opposing one surface of the second drive unit 442 to which the second contact portion 441 is coupled. According to an example embodiment, the elastic portion 445 may include a spring having elastic force. Accordingly, the elastic portion 445 may provide elastic force in a direction of movement (for example, second direction 4) of the second contact portion 441. In addition, the elastic portion 445 may be designed to have an elastic modulus, causing damage to the substrate W, when the second correction unit 440 is in contact with the third point on the side surface of the substrate W.

The displacement measurement unit 446 may measure displacement of the second drive unit 442. The displacement measurement unit 446 according to an example embodiment may be a proximity sensor, oscillating a predetermined wavelength toward a target object and receiving a wavelength reflected from the target object to measure a distance to the target object. The target object according to an example embodiment may be the second drive unit 442. The displacement measurement unit 446 may be disposed on an upper surface of the body 443. According to an example embodiment, the displacement measurement unit 446 may be disposed at an upper end of the body 443.

A displacement value of the second drive unit 442 may be measured with respect to a plurality of points on the side surface of the substrate W. While the chuck 331 rotates the substrate W, a displacement value of the second drive unit 442 may be measured using the displacement measurement unit 466 at the plurality of points, for example, a first measurement point P1, a second measurement point P2, a third measurement point P3, and a fourth measurement point P4, and eccentricity of the substrate W may be measured based on information on a plurality of displacement values for respective points. In an example embodiment, the first measurement point P1, the second measurement point P2, the third measurement point P3, and the fourth measurement point P4 may be disposed at an interval of 90 degrees with respect to a center of the substrate W.

For example, a displacement difference of 40 micrometers may occur at the first measurement point P1, as compared to a normal state, and a displacement difference of 40 micrometers may occur at the third measurement point P3, as compared to the normal state. In this case, a center C′ of the substrate W to be treated may be determined to be eccentric downwardly by 20 micrometers from a center C of the chuck 331 on a Y-axis.

Accordingly, a substrate treatment apparatus including an eccentricity correction unit 400 correcting eccentricity of a substrate W supported by a support unit 330 according to an example embodiment of the present disclosure, the substrate treatment apparatus may include a first correction unit 410 including first contact portions 422 and 432 in contact with a plurality of points of a side surface of the substrate W having a notch formed in a periphery thereof, and first drive units 426 and 436 moving a position of the substrate W such that a center of the substrate W corresponds to a center of the support unit 330, and a second correction unit 440 including a second contact portion 411 in contact with the other side surface of the substrate W having a notch formed in a periphery thereof, a second drive unit 442 configured to change a position of the second contact portion 411, and an elastic portion 445 configured to provide elastic force in a direction of movement of the second contact portion 411 to press or depressurize the substrate W.

The first correction unit 410 may be in contact with a plurality of points, sharing one axis on a horizontal plane, among the points, and the second correction unit 420 may be in contact with a point belonging to an axis, different from the one axis. A repeated description will be omitted.

In addition, when the second contact portion 441 may be in contact with the substrate W, the second contact portion 441 may be in contact with the notch formed in the periphery of the substrate W. In this case, a notch error N may vary depending on a shape of the second contact portion 441, and the notch error N may be minimized depending on the shape of the second contact portion 441. When the notch error N is minimized, the notch error N may be present within a preset allowable eccentricity value, even when the second contact portion 441 is in contact with the notch. Thus, it may be unnecessary to perform notch avoidance correction.

In an example embodiment therefor, as illustrated in FIG. 3, a portion of the second contact portion 411 in contact with the other side surface of the substrate W may be configured to be flat.

A distance between a tangent to a circumferential surface that would have been formed had it not been for the notch and a straight line to the second contact portion 411 in contact with the substrate W may be a notch error N1. The second contact portion 411 may be configured to be flat, such that the notch error N1 may be minimized.

In addition, a length of the portion of the second contact portion 411 in contact with the other side surface of the substrate W may be greater than or equal to a length of the notch. The portion of the second contact portion 411 having one surface longer than the notch may not enter the notch, such that only a minimum notch error may be formed between the portion of the second contact portion 411 and the tangent to the circumferential surface that would have been formed had it not been for the notch.

In addition, when it is determined that the second correction unit 440 is in contact with one side surface of the substrate W including the notch, that is, the second contact portion 441 is in contact with the notch of the substrate W and eccentricity is present in the substrate W, the first correction unit 410 may move a position of the substrate W by half of a degree of eccentricity in a direction in which the notch is formed. Eccentricity may be corrected by half of N1 in a negative direction of the second direction 4.

For example, when the preset allowable eccentricity value is 15 μm, the notch error N1 illustrated in FIG. 3 may be 5.21 μm, and thus an amount of eccentricity correction may be 2.6 μm, 5.21 μm/2. Accordingly, the notch error may be present within the preset allowable eccentricity value without correction, such that it may be unnecessary to perform a control process to detect the notch or avoid the notch to be in contact with the substrate W.

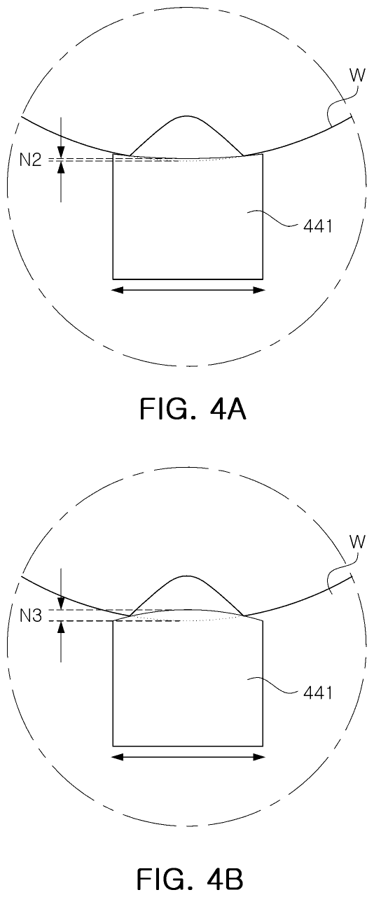

Alternatively, in another example embodiment, as illustrated in FIG. 4A, the portion of the second contact portion 411 in contact with the other side surface of the substrate W may include a concave portion, and a length of the concave portion may be configured to be greater than or equal to the length of the notch.

A distance between a tangent to the circumferential surface that would have been formed had it not been for the notch and a straight line to a center of the concave portion of the second contact portion 411 may be a notch error N2. In this case, a curvature of the concave portion may be configured to be less than or equal to a curvature of the substrate, thereby minimizing the notch error N2.

The length of the concave portion, illustrated by the arrow of FIG. 4A, may be configured to be greater than or equal to the length of the notch to prevent the second contact portion 411 from entering the notch. At the same time, the curvature of the concave portion may be configured to be less than or equal to the curvature of the substrate W, such that the second contact 411 may not be excessively out of the notch.

In other words, the length of the portion of the second contact portion 411 in contact with the other side surface of the substrate W, greater than or equal to the length of the notch, may have a curved surface longer than the notch, and thus may not enter the notch, such that only a minimum notch error N2 may be formed between the portion of the second contact portion 411 and the tangent to the circumferential surface that would have been formed had it not been for the notch.

In addition, when it is determined that the second correction unit 440 is in contact with one side surface of the substrate W including the notch, that is, the second contact portion 441 is in contact with the notch of the substrate W and eccentricity is present in the substrate W, the first correction unit 410 may move a position of the substrate W in consideration of a curvature of the second contact portion 440 in a direction in which the notch is formed.

Alternatively, in another example embodiment, as illustrated in FIG. 4B, the portion of the second contact portion 411 in contact with the other side surface of the substrate W may include a convex portion, and a length of the convex portion may be configured to be greater than or equal to the length of the notch.

A distance between a tangent to the circumferential surface that would have been formed had it not been for the notch and a straight line to a center of the convex portion of the second contact portion 411 may be a notch error N3. In this case, a curvature of the convex portion may be configured to be less than or equal to a curvature of the substrate, thereby minimizing the notch error N3.

The length of the convex portion, illustrated by the arrow of FIG. 4B, may be configured to be greater than or equal to the length of the notch, such that the second contact portion 411 may not be in contact with the deep inside of the notch but be in contact with a portion close to a side surface of the substrate W. At the same time, the curvature of the convex portion may be configured to be less than or equal to the curvature of the substrate W, such that the second contact 411 may not be excessively out of the notch.

In other words, the length of the portion of the second contact portion 411 in contact with the other side surface of the substrate W, greater than or equal to the length of the notch, may have a curved surface longer than the notch, and thus may not enter the notch, such that only a minimum notch error N3 may be formed between the portion of the second contact portion 411 and the tangent to the circumferential surface that would have been formed had it not been for the notch.

In addition, when it is determined that the second correction unit 440 is in contact with one side surface of the substrate W including the notch, that is, the second contact portion 441 is in contact with the notch of the substrate W and eccentricity is present in the substrate W, the first correction unit 410 may move a position of the substrate W in consideration of a curvature of the second contact portion 440 in a direction in which the notch is formed.

A displacement measurement unit 446 of the second correction unit 440 according to an example embodiment may measure eccentricity of the substrate W at different points of the substrate W, when the second contact portion 441 rotates the substrate W at a predetermined angle on a horizontal plane, for example, a first measurement point P1, a second measurement point P2, a third measurement point P3, and a fourth measurement point P4. The first correction unit 410 may move, using measured eccentricity of the substrate W, a position of the substrate W by half of a degree of eccentricity of the substrate W measured in a direction, parallel to one axis, and a direction, perpendicular to the one axis, on the horizontal plane. That is, the degree of eccentricity of the substrate W may be measured with respect to both an X-axis and a Y-axis, and the position of the substrate W may be moved with respect to both the X-axis and Y-axis.

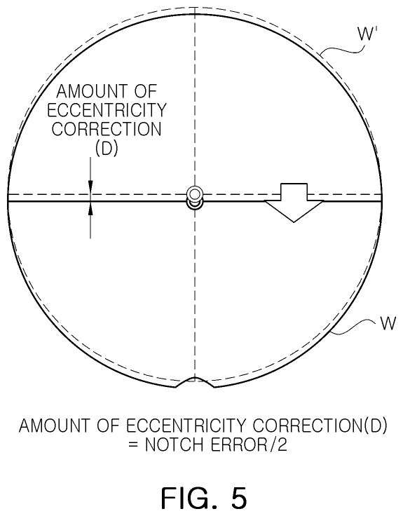

As illustrated in FIG. 5, according to an example embodiment of the present disclosure, when a notch error is measured with respect to the substrate W′, before correction is performed, that is in a correct position thereof, the first correction unit 410 may move the substrate W′, together with the substrate W on which correction is performed. When the notch error is N, N/2 may be used as an amount of eccentricity correction (D) to move the substrate W′ by N/2 in a negative direction of the second direction 4.

For example, when a preset allowable eccentricity value is 15 μm, the notch error N illustrated in FIG. 5 may be 5.21 μm, and thus an amount of eccentricity correction may be 2.6 μm, 5.21 μm/2. Accordingly, the notch error may be present within the preset allowable eccentricity value without correction, such that it may be unnecessary to perform a control process to detect the notch or avoid the notch to be in contact with the substrate W.

When the second contact portion 441 is configured to be flat, the substrate may be moved by half of the notch error N when displacement is measured when the second contact portion 441 is in contact with the notch. When the second contact portion 441 is configured to be concave or convex, the amount of eccentricity correction (D) may be determined by considering a measured degree of eccentricity of the substrate, that is, a curvature of the second contact portion 441, with respect to the notch error N.

The position of the substrate may be moved in a direction in which the notch is formed, that is, a negative direction of the second direction 4, by the determined amount of eccentricity correction. A direction of movement of the substrate is not limited to the above axis, and the direction of movement of the substrate may be determined depending on a direction in which the notch is positioned.

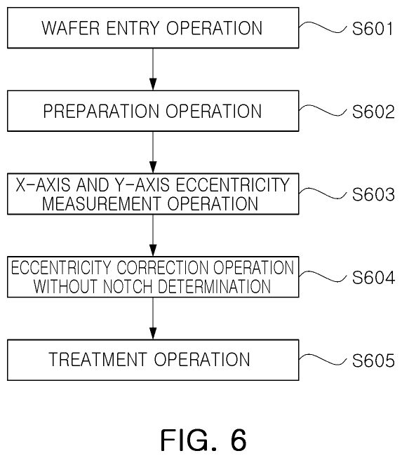

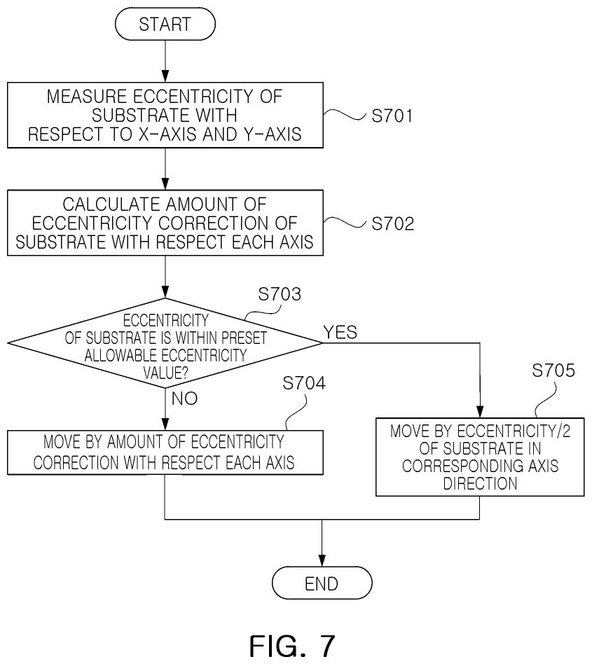

FIG. 6 illustrates an eccentricity correction method according to an example embodiment of the present disclosure. FIG. 7 illustrates a specific eccentricity correction method according to an example embodiment of the present disclosure.

As illustrated in FIG. 6, a substrate treating method including an eccentricity correction unit 400 according to an example embodiment of the present disclosure may include a wafer entry operation (S601) of entering a wafer into a process chamber 300, a preparation operation (S602) of mounting a substrate W on a support unit 330, a X-axis and Y-axis eccentricity measurement operation (S603) of measuring eccentricity of the substrate W having a notch formed in a periphery thereof, an eccentricity correction operation (S604) of correcting eccentricity of the substrate (W) depending on a degree of measured eccentricity of the substrate W, and a treatment operation (S605) of treating the substrate W having corrected eccentricity.

In the eccentricity correction operation (S604), a center of the substrate W to be treated may be allowed to correspond to a center of a chuck 331 within an error range by contact with a plurality of points, included on one axis, of a side surface of the substrate W supported by the chuck 331 and a point included on an axis, different from the one axis, and the eccentricity correction operation may be performed in the same manner, even when the notch is included at the point.

In other words, the eccentricity correction operation (S604) may be an operation of performing eccentricity correction depending on measured eccentricity without notch determination.

In an example embodiment, the eccentricity measurement operation (S603) may include an operation of measuring eccentricity of the substrate W at different points of the substrate W, when the substrate W is rotated at a predetermined angle on a horizontal plane. Eccentricity of the substrate w may include eccentricity in a direction, parallel to the one axis, and a direction, perpendicular to the one axis, on the horizontal plane.

In addition, in the eccentricity measurement operation (S603), when eccentricity is measured with respect to the notch of the substrate W, and a second contact portion 440 for measuring the eccentricity is configured to be flat, the eccentricity correction operation (S604) may further include an operation of moving, using measured eccentricity of the substrate W, a position of the substrate W by half of a degree of eccentricity of the substrate W measured in the direction, parallel to the one axis, and the direction, perpendicular to the one axis, on the horizontal plane.

In the eccentricity measurement operation (S603), when eccentricity is measured with respect to a periphery of the substrate W excluding the notch, and the second contact portion 440 for measuring the eccentricity is configured to be flat, the eccentricity correction operation (S604) may further include the operation of moving, using measured eccentricity of the substrate W, the position of the substrate W by half of the degree of eccentricity of the substrate W measured in the direction, parallel to the one axis, and the direction, perpendicular to the one axis, on the horizontal plane.

That is, when the second contact portion 440 is configured to be flat, and the eccentricity correction unit 400 corrects eccentricity in both the direction, parallel to the one axis, and the direction, perpendicular to the one axis, on the horizontal plane, eccentricity correction may be performed in the same manner, when the second contact portion 440 is in contact with the notch or when the second contact portion 440 is in contact with a portion excluding the notch.

In another example embodiment, in the eccentricity measurement operation (S603), when eccentricity is measured with respect to the periphery of the substrate W excluding the notch, and the second contact portion 440 for measuring the eccentricity includes a concave portion having a length greater than or equal to a length of the notch, the eccentricity correction operation (S604) may further include the operation of moving, using measured eccentricity of the substrate W, the position of the substrate W by an amount of eccentricity correction determined by considering a curvature of the concave portion with respect to the degree of eccentricity of the substrate W measured in the direction, parallel to the one axis, and the direction, perpendicular to the one axis, on the horizontal plane.

In addition, in the eccentricity measurement operation (S603), when eccentricity is measured with respect to the periphery of the substrate W excluding the notch, and the second contact portion 440 for measuring the eccentricity includes the concave portion having the length greater than or equal to the length of the notch, the eccentricity correction operation (S604) may further include the operation of moving, using measured eccentricity of the substrate W, the position of the substrate W by the amount of eccentricity correction determined by considering the curvature of the concave portion with respect to the degree of eccentricity of the substrate W measured in the direction, parallel to the one axis, and the direction, perpendicular to the one axis, on the horizontal plane.

In other words, the second contact portion 440 includes the concave portion formed to be concave and longer than the notch, and the eccentricity correction unit 400 corrects eccentricity in both the direction, parallel to the one axis, and the direction, perpendicular to the one axis, on the horizontal plane, eccentricity correction may be performed in the same manner, when the second contact portion 440 is in contact with the notch or when the second contact portion 440 is in contact with a portion excluding the notch.

In another example embodiment, in the eccentricity measurement operation (S603), when eccentricity is measured with respect to the notch of the substrate W, and the second contact portion 440 for measuring the eccentricity includes a convex portion having a curvature less than or equal to a curvature of the substrate W, the eccentricity correction operation (S604) may further include an operation of moving, using measured eccentricity of the substrate W, the position of the substrate W by an amount of eccentricity correction determined by considering a curvature of the convex portion with respect to a degree of eccentricity of the substrate W measured in the direction, parallel to the one axis, and the direction, perpendicular to the one axis, on the horizontal plane.

In addition, in the eccentricity measurement operation (S603), when eccentricity is measured with respect to a periphery of the substrate W excluding the notch, and the second contact portion 440 for measuring the eccentricity includes the concave portion having the curvature less than or equal to the curvature of the substrate W, the eccentricity correction operation (S604) may further include an operation of moving, using measured eccentricity of the substrate W, the position of the substrate W by the amount of eccentricity correction determined by considering the curvature of the convex portion with respect to the degree of eccentricity of the substrate W measured in the direction, parallel to the one axis, and the direction, perpendicular to the one axis, on the horizontal plane.

Similarly, the second contact portion 440 includes the convex portion formed to be convex and longer than the notch, and the eccentricity correction unit 400 corrects eccentricity in both the direction, parallel to the one axis, and the direction, perpendicular to the one axis, on the horizontal plane, eccentricity correction may be performed in the same manner, when the second contact portion 440 is in contact with the notch or when the second contact portion 440 is in contact with a portion excluding the notch.

Accordingly, as illustrated in FIG. 7, eccentricity of the substrate W with respect to an X-axis and a Y-axis may be measured (S701), and an amount of eccentricity correction of the substrate W with respect to each axis may be calculated (S702). Measurement and correction of eccentricity of the substrate W may be performed with respect to a plurality of axes.

Then, when eccentricity of the substrate W is within a preset allowable eccentricity value (“YES” in S703), movement may be performed by half (eccentricity/2) of a degree of eccentricity of the substrate W in a corresponding axis direction (S705). Eccentricity correction of the substrate W may be performed with respect to both an X-axis and a Y-axis, and thus a preset allowable eccentricity value may be set. Even when eccentricity is measured with respect to the notch, movement may be performed by a notch error, that is, by half of the degree of eccentricity of the substrate W to correspond to eccentricity correction.

When eccentricity of the substrate W exceeds the preset allowable eccentricity value (“NO” in S703), movement may be performed by an amount of eccentricity correction with respect to each axis (S704).

In the description of the example embodiment, “ . . . portion” or “ . . . unit” may be implemented in various manners, for example, a processor, program instructions executed by the processor, software module, microcode, computer program product, logic circuit, application-specific integration circuitry, firmware, and the like.

The method disclosed in the example embodiments may be directly implemented by a hardware processor, or may be implemented and completed by a combination of a hardware module and a software module among processors. The software module may be stored in conventional storage media such as random access memory (RAM), flash memory, read-only memory (ROM), programmable ROM or electrically erasable programmable memory, register, or the like. The storage medium may be disposed in a memory, and the processor may read information stored in the memory and may combine with the hardware to complete the above-described method. A repeated description will be omitted herein.

In an implementation process, the method may be completed through an integrated logic circuit of hardware in the processor or an instruction in the form of software. The method described in combination with the example embodiment of the present disclosure may be directly implemented as being executed by a hardware processor, or being executed by a combination of hardware and software modules in the processor. The software module may be stored in a conventional storage medium such as RAM, flash memory, ROM, programmable ROM or electrically erasable programmable memory, a register, or the like. The storage medium may be positioned in the memory, and the processor may read information in the memory and complete the method in combination with the hardware thereof.

That is, a person skilled in the art may be aware that the units and algorithm steps in the examples described with reference to the example embodiments described herein may be implemented by electronic hardware or a combination of computer software and electronic hardware. Whether such functions are performed by hardware or software depends on particular applications and design constraints of the technical solutions. A person skilled in the art may use different methods to implement the above-described functions for each particular application, but it should not be considered that the implementation goes beyond the scope of the disclosure.

In some example embodiments provided in the present application, it should be understood that the device and method described herein may be implemented in other manners. For example, the above-described device example embodiment is merely an example. For example, division of the units is merely division of logical functions, and may be other division in actual implementation. For example, a plurality of units or components may be combined or integrated into another system, or some components may be ignored or may not be performed. In addition, mutual couplings, direct couplings, or communication connections displayed or discussed may be indirect couplings or communication connections implemented using some interfaces, devices or units, and may be implemented in electrical, mechanical, or other form.

The units described above as separate parts may be physically separated from each other, and parts displayed as units may be or may not be physical units. Thus, the parts may be disposed in one position, or may be distributed on a plurality of network units. Some or all of the units may be selected based on actual requirements to achieve aspects of the present disclosure.

That is, functional units in the example embodiments of the present disclosure may be integrated into one processing unit, or each of the units may be present solely, or two or more units are integrated into one unit.

When the functions are implemented in a form of a software functional unit and are sold or used as an independent product, the functions may be stored in a non-transitory computer-readable storage medium. Based on such an understanding, the technical solution of the present application, in essence, or the part contributing to the related technology or the part of the technical solution may be implemented in the form of a software product, and the computer software product is stored in a storage medium and includes several instructions for enabling a computer device (which may be a personal computer, a server, or a network device, or the like) to perform all or part of the steps described in methods in the example embodiments of the present disclosure. The above-described storage medium includes various media capable of storing program codes, such as a U disk, a mobile hard disk, a ROM, a RAM, a magnetic disk, or an optical disk.

While example embodiments have been illustrated and described above, it will be apparent to those skilled in the art that modifications and variations could be made without departing from the scope of the present disclosure as defined by the appended claims.

What is claimed is:

1. A substrate treatment apparatus including an eccentricity correction unit correcting eccentricity of a substrate supported by a support unit, the substrate treatment apparatus comprising:
a first correction unit including a first contact portion in contact with a plurality of points of a side surface of the substrate having a notch formed in a periphery thereof, and a first drive unit configured to move a position of the substrate such that a center of the substrate corresponds to a center of the support unit; and
a second correction unit including a second contact portion in contact with the other side surface of the substrate having the notch formed in the periphery thereof, a second drive unit configured to change a position of the second contact portion, and an elastic portion configured to provide elastic force in a direction of movement of the second contact portion to press or depressurize the substrate,
wherein a portion of the second contact portion in contact with the other side surface of the substrate is configured to be flat.

2. The substrate treatment apparatus of claim 1, wherein a length of the portion of the second contact portion in contact with the other side surface of the substrate is greater than or equal to a length of the notch.

3. The substrate treatment apparatus of claim 1, wherein
when the second correction unit is in contact with one side surface of the substrate including the notch and determines that eccentricity is present in the substrate,
the first correction unit is configured to move the position of the substrate by half of the eccentricity in a direction in which the notch is formed.

4. The substrate treatment apparatus of claim 3, further comprising:
a displacement measurement unit configured to measure eccentricity of the substrate according to displacement of the second drive unit due to elastic force of the elastic portion,
wherein measurement unit is the displacement configured to measure eccentricity of the substrate at different points of the substrate, when the second contact portion rotates the substrate at a predetermined angle on a horizontal plane.

5. The substrate treatment apparatus of claim 4, wherein the first correction unit is configured to move, using measured eccentricity of the substrate, the position of the substrate by half of a degree of eccentricity of the substrate measured in a direction, parallel to one axis, and a direction, perpendicular to the one axis, on the horizontal plane.

6. A substrate treatment apparatus including an eccentricity correction unit correcting eccentricity of a substrate supported by a support unit, the substrate treatment apparatus comprising:
a first correction unit including a first contact portion in contact with a plurality of points of a side surface of the substrate having a notch formed in a periphery thereof, and a first drive unit configured to move a position of the substrate such that a center of the substrate corresponds to a center of the support unit; and
a second correction unit including a second contact portion in contact with the other side surface of the substrate having the notch formed in the periphery thereof, a second drive unit configured to change a position of the second contact portion, and an elastic portion configured to provide elastic force in a direction of movement of the second contact portion to press or depressurize the substrate,
wherein the first correction unit is in contact with a plurality of points, included one axis on a horizontal plane, among the points, and
the second correction unit is in contact with a point included on an axis, parallel to the one axis.

7. The substrate treatment apparatus of claim 6, wherein a portion of the second contact portion in contact with the other side surface of the substrate includes a concave portion, and a length of the concave portion is configured to be greater than or equal to a length of the notch.

8. The substrate treatment apparatus of claim 7, wherein a curvature of the concave portion is less than or equal to a curvature of the substrate.

9. The substrate treatment apparatus of claim 6, wherein a portion of the second contact portion in contact with the other side surface of the substrate includes a convex portion, and a length of the convex portion is configured to be greater than or equal to a length of the notch.

10. The substrate treatment apparatus of claim 9, wherein a curvature of the convex portion is less than or equal to a curvature of the substrate.

11. The substrate treatment apparatus of claim 6, wherein
when the second correction unit is in contact with one side surface of the substrate including the notch and determines that eccentricity is present in the substrate,
the first correction unit is configured to move the position of the substrate in a direction, in which the notch is formed, by an amount of eccentricity correction determined by considering a curvature of the second contact portion and a degree of measured eccentricity of the substrate.

12. The substrate treatment apparatus of claim 6, wherein
a displacement measurement unit configured to measure eccentricity of the substrate according to displacement of the second drive unit due to elastic force of the elastic portion,
wherein the displacement measurement unit is configured to measure eccentricity of the substrate at different points of the substrate, when the second contact portion rotates the substrate at a predetermined angle on the horizontal plane.

13. A method for treating a substrate, the method comprising:
a preparation operation of mounting a substrate to be treated on a support unit;
an eccentricity measurement operation of measuring eccentricity of the substrate having a notch formed in a periphery thereof;
an eccentricity correction operation of correcting eccentricity of the substrate depending on a degree of eccentricity of the substrate measured in the eccentricity measurement operation; and
a treatment operation of treating the substrate having corrected eccentricity,
wherein, in the eccentricity correction operation, a center of the substrate to be treated is allowed to correspond to a center of a chuck within an error range by contact with a plurality of points, included on one axis, of a side surface of the substrate supported by the chuck and a point included on an axis, different from the one axis, and
the eccentricity correction operation is performed in the same manner, even when the notch is included at the point.

14. The method of claim 13, wherein
the eccentricity correction operation includes an operation of measuring eccentricity of the substrate at different points of the substrate, when the substrate is rotated at a predetermined angle on a horizontal plane, and
eccentricity of the substrate includes eccentricity in a direction, parallel to the one axis, and a direction, perpendicular to the one axis, on the horizontal plane.

15. The method of claim 14, wherein
in the eccentricity measurement operation, when eccentricity is measured with respect to the notch of the substrate, and a second contact portion for measuring the eccentricity is configured to be flat,
the eccentricity correction operation further includes an operation of moving, using measured eccentricity of the substrate, a position of the substrate by half of a degree of eccentricity of the substrate measured in the direction, parallel to the one axis, and the direction, perpendicular to the one axis, on the horizontal plane.

16. The method of claim 15, wherein
in the eccentricity measurement operation, when eccentricity is measured with respect to a periphery of the substrate excluding the notch, and the second contact portion for measuring the eccentricity is configured to be flat,
the eccentricity correction operation further includes an operation of moving, using measured eccentricity of the substrate, the position of the substrate by half of the degree of eccentricity of the substrate measured in the direction, parallel to the one axis, and the direction, perpendicular to the one axis, on the horizontal plane.

17. The method of claim 14, wherein
in the eccentricity measurement operation, when eccentricity is measured with respect to the notch of the substrate, and the second contact portion for measuring the eccentricity includes a concave portion having a length greater than or equal to a length of the notch,
the eccentricity correction operation further includes an operation of moving, using measured eccentricity of the substrate, a position of the substrate by an amount of eccentricity correction determined by considering a curvature of the concave portion with respect to a degree of eccentricity of the substrate measured in the direction, parallel to the one axis, and the direction, perpendicular to the one axis, on the horizontal plane.

18. The method of claim 17, wherein
in the eccentricity measurement operation, when eccentricity is measured with respect to a periphery of the substrate excluding the notch, and the second contact portion for measuring the eccentricity includes the concave portion having the length greater than or equal to the length of the notch,
the eccentricity correction operation further includes the operation of moving, using measured eccentricity of the substrate, the position of the substrate by the amount of eccentricity correction determined by considering the curvature of the concave portion with respect to the degree of eccentricity of the substrate measured in the direction, parallel to the one axis, and the direction, perpendicular to the one axis, on the horizontal plane.

19. The method of claim 14, wherein
in the eccentricity measurement operation, when eccentricity is measured with respect to the notch of the substrate, and the second contact portion for measuring the eccentricity includes a convex portion having a curvature less than or equal to a curvature of the substrate,
the eccentricity correction operation further includes an operation of moving, using measured eccentricity of the substrate, a position of the substrate by an amount of eccentricity correction determined by considering a curvature of the convex portion with respect to a degree of eccentricity of the substrate measured in the direction, parallel to the one axis, and the direction, perpendicular to the one axis, on the horizontal plane.

20. The method of claim 19, wherein
in the eccentricity measurement operation, when eccentricity is measured with respect to a periphery of the substrate excluding the notch, and the second contact portion for measuring the eccentricity includes the concave portion having the curvature less than or equal to the curvature of the substrate,
the eccentricity correction operation further includes the operation of moving, using measured eccentricity of the substrate, the position of the substrate by the amount of eccentricity correction determined by considering the curvature of the convex portion with respect to the degree of eccentricity of the substrate measured in the direction, parallel to the one axis, and the direction, perpendicular to the one axis, on the horizontal plane.
